(19) United States
(12) Patent Application Publication
(10) Pub. No.: US 2026/0172036 A1
(43) Pub. Date: Jun. 18, 2026

(54) DUAL-MODE DIGITAL-TO-TIME CONVERTER FOR PHASE-LOCKED LOOP

(71) Applicant: RAMSCHIP, INC., Seongnam-si (KR)

(72) Inventors: Jaegan KO, Seongnam-si (KR); Deoksoo KIM, Seoul (KR); Bongjoon LEE, Seongnam-si (KR)

(21) Appl. No.: 19/415,239

(22) Filed: Dec. 10, 2025

(30) Foreign Application Priority Data
Dec. 12, 2024 (KR) 10-2024-0185117

(51) Int. Cl. H03L 7/085; G04F 10/00; H03L 7/081; H03L 7/197

(52) U.S. Cl. CPC H03L 7/085; G04F 10/00; H03L 7/081; H03L 7/1974

(57) ABSTRACT

A dual-mode digital-to-time converter for a phase-locked loop includes a ring oscillator mode and a DTC mode, a delay control word configured to cause total delay time of the dual-mode digital-to-time converter to be second delay time while the dual-mode digital-to-time converter operates as a ring oscillator is determined in the ring oscillator mode, the DTC output clock signal is output in the DTC mode when the delay control word determined in the ring oscillator mode is fixed, and a resolution and a dynamic range sufficient to remove quantization noise of a fractional divider is ensured while reducing a power consumption and having a reduced area.

### BACKGROUND OF THE DISCLOSURE

### Field of the Disclosure

The present disclosure relates to a dual-mode digital-to-time converter for a phase-locked loop.

### Background of the Related Art

Phase-locked loops (PLLs) are used to synchronize circuits in various electronic devices.

The PLLs may be classified into an integer-N PLL configured to generate a clock signal corresponding to an integer multiple of a reference signal, and a fractional-N PLL for generating a clock signal corresponding to a fractional multiple of a reference signal. In many cases, since several devices with various specifications need different frequencies, the fractional-N PLL capable of generating various frequency signals from a single reference signal is preferred. However, in general, the fractional-N PLL has a problem such that PLL performance deteriorates due to occurrence of fractional spurs caused by quantization noise of a fractional divider used for frequency synthesis. Accordingly, there have been many attempts to remove the quantization noise using a digital-to-time converter (DTC). This technology is also introduced in Patent Document 1.

In a case of the DTC configured to remove quantization noise of a fractional divider, when the DTC has a resolution sufficiently smaller than a quantization step of the fractional divider and a dynamic range equal to or greater than the quantization step is secured, remaining quantization errors may be reduced by a loop filter of the PLL, etc.

Meanwhile, the DTC has a trade-off relationship between an area, a power consumption, a resolution, and a dynamic range. Thus, in a case of a precise DTC, a power consumption is increased, and a larger area is needed, and a dynamic range may be limited. Therefore, there is a need to develop a DTC capable of reducing power consumption and having a reduced area while having a resolution and an output range sufficient to remove quantization noise of fractional dividers.

The background technology described above is technical information already possessed to derive the present disclosure or acquired in a process of deriving the present disclosure by the inventor, and is not necessarily deemed as the well-known technology known to the public before the filing of the present application.

### Prior Art Document

### Patent Document

(Patent Document 1) U.S. Pat. No. 8,497,716 B

### SUMMARY OF THE DISCLOSURE

One aspect of the present disclosure is to provide a dual-mode digital-to-time converter for a phase-locked loop, the dual-mode digital-to-time converter capable of reducing power consumption and having a reduced area while having a resolution and a dynamic range sufficient to remove quantization noise used in a fractional divider.

One aspect of the present disclosure is to provide a dual-mode digital-to-time converter capable of performing calibration on an on-time (real-time) basis without interrupting a digital-to-time converter (DTC) or phase-locked loop (PLL) operation.

To accomplish the above-mentioned objects, according to one aspect of the present disclosure, there is provided a dual-mode digital-to-time converter for a phase-locked loop, the dual-mode digital-to-time converter being configured to be utilized for a phase-locked loop including a fractional divider, wherein the dual-mode digital-to-time converter may provide, to the phase-locked loop, a digital-to-time converter (DTC) output clock signal (DTC_out) that has delayed a reference clock signal (REF) by first delay time, an operating mode of the dual-mode digital-to-time converter may include a ring oscillator mode and a DTC mode, a delay control word (DCW) configured to cause total delay time of the dual-mode digital-to-time converter to be second delay time may be determined in the ring oscillator mode, and the DTC output clock signal may be output in the DTC mode when the delay control word determined in the ring oscillator mode is fixed.

At this time, the dual-mode digital-to-time converter may include a first multiplexer, a programmable delay line, and a second multiplexer, the reference clock signal may be applied through a first input terminal of the first multiplexer, an output terminal of the first multiplexer may be connected to an input stage of the programmable delay line, a first output stage of the programmable delay line may be connected to a second input terminal of the first multiplexer, a second output stage of the programmable delay line may be connected to an input terminal of the second multiplexer, and an output terminal of the second multiplexer may outputs the DTC output clock signal.

In addition, the programmable delay line may include delay units, and an output stage of each of the delay units may be connected to the input terminal of the second multiplexer.

In addition, the first delay time may be determined by a phase control word (PCW) applied to the second multiplexer, with respect to the delay units, N delay units may be arranged and characteristics of the delay units may be identical to each other within a margin of error, and the first delay time may be adjusted in units of 1/N of the second delay time.

In addition, the programmable delay line may include a first delay unit, a second delay unit, and a third delay unit, an input terminal of the first delay unit may be connected to the input stage of the programmable delay line, an output terminal of the first delay unit may be connected to an input terminal of the second delay unit and the input terminal of the second multiplexer, and an output terminal of the second delay unit may be connected to an input terminal of the third delay unit and the input terminal of the second multiplexer.

In addition, a number of delay units included in the programmable delay line may be N, the Nth delay unit may include a first output terminal and a second output terminal, a first output terminal of the Nth delay unit may be connected to the first output stage of the programmable delay line, a second output terminal of the Nth delay unit may be connected to the second output stage of the programmable delay line, the first delay time may be determined by a phase control word (PCW) applied to the second multiplexer, characteristics of the delay units may be identical to each other within a margin of error, and the first delay time may be adjusted in units of 1/N of the second delay time.

In addition, the dual-mode digital-to-time converter may include a programmable delay line including a first delay unit to an Nth delay unit, and a second multiplexer, an input multiplexer and a delay element may be included in each of the first delay unit to the Nth delay unit, one input terminal of the input multiplexer included in the first delay unit may be connected to a first output stage of the programmable delay line, a reference clock signal may be applied to another input terminal of the input multiplexer included in the first delay unit, an output terminal of a previous delay unit may be connected to another input terminal of each of the input multiplexers included in the second to Nth delay units, a mode control signal may be applied to a control terminal of the input multiplexer provided in the first delay unit, a first control signal may be applied to a control terminal of each of the input multiplexers included in the second delay unit to the Nth delay unit, and the first control signal may be a control signal configured to output a signal, the signal being output from the output stage of the previous delay unit.

In addition, the dual-mode digital-to-time converter may include a first dual-mode digital-to-time converter and a second dual-mode digital-to-time converter, the second dual-mode digital-to-time converter may operate in the ring oscillator mode to set the delay control word while the first dual-mode digital-to-time converter operates in the DTC mode, and the second dual-mode digital-to-time converter, having operated in the ring oscillator mode, may be changed into the DTC mode and output the DTC output clock signal instead of the first dual-mode digital-to-time converter.

In addition, the dual-mode digital-to-time converter may further include an auxiliary programmable delay line connected between the first input terminal of the first multiplexer and an input side of the reference clock signal, the auxiliary programmable delay line may receive an input of a reference clock signal instead of the first multiplexer, and delay the reference clock signal in correspondence with an auxiliary delay control word (DCW′) to provide the delayed reference clock signal to the first multiplexer and the second multiplexer.

The dual-mode digital-to-time converter according to one embodiment of the present disclosure may further include a transition detector configured to sample delay unit output signals output from the delay units, respectively, and detect a number of transitions which occur in the delay unit output signals during predetermined time; and a decision logic configured to check whether the number of the transitions detected by the transition detector matches an expected number of transitions in a normal state.

At this time, the transition detector may sample the delay unit output signals using an output clock signal of the phase-locked loop, and the delay control word may be calibrated to increase the second delay time when a value obtained by subtracting an expected value of transitions in the normal state from the number of the transitions detected by the transition detector is greater than a predetermined reference value. For example, when the expected value in the normal state is 4 and the detected number of the transitions is 5, this indicates that the second delay time is reduced. At this time, when a delay control word needed to lower the detected number of the transitions by one step is known in advance, the corresponding delay control word may be reflected in a previous delay control word to calibrate the delay control word.

To accomplish the above-mentioned objects, according to one aspect of the present disclosure, there is provided a digital-to-time converter having a calibration function, the digital-to-time converter being configured to be utilized for a phase-locked loop including a fractional divider, wherein the digital-to-time converter may provide, to the phase-locked loop, a digital-to-time converter (DTC) output clock signal (DTC_out) which has delayed a reference clock signal (REF) by first delay time, and the digital-to-time converter may further include: a programmable delay line including a plurality of delay units; a transition detector configured to sample delay unit output signals output from the delay units, respectively, and detect a number of transitions which occur in the delay unit output signals during predetermined time; and a decision logic configured to check whether the number of the transitions detected by the transition detector matches an expected number of transitions in a normal state.

In addition, the digital-to-time converter may further include a multiplexer having an input terminal thereof to which an output stage of each of the plurality of delay units is connected, and configured to output the DTC output clock signal via an output terminal thereof.

At this time, total delay time of the programmable delay line may be determined as second delay time by a delay control word, the first delay time may be determined by a phase control word (PCW) applied to the multiplexer, the transition detector may sample the delay unit output signals using an output clock signal (PLL_out) of the phase-locked loop, and the delay control word may be calibrated to increase the second delay time when a value obtained by subtracting an expected value of transitions in the normal state from the number of the transitions detected by the transition detector is greater than a predetermined reference value..

In addition, with respect to the plurality of delay units, N delay units may be arranged and characteristics of the plurality of delay units may be identical to each other within a margin of error, and the first delay time may be adjusted in units of 1/N of the second delay time.

Additionally, the predetermined time may be determined as being less than or equal to a half period of a PLL clock output signal output from the phase-locked loop.

In addition, an operating mode of the digital-to-time converter may include a ring oscillator mode and a DTC mode, a delay control word (DCW) configured to cause total delay time of the dual-mode digital-to-time converter to be second delay time may be determined in the ring oscillator mode, and the DTC output clock signal may be output in the DTC mode when the delay control word determined in the ring oscillator mode is fixed.

### BRIEF DESCRIPTION OF THE DRAWINGS

The above and other objects, features and advantages of the present disclosure will be apparent from the following detailed description of the embodiments of the disclosure in conjunction with the accompanying drawings, in which:

FIG. 1 is a schematic diagram illustrating an example of a fractional-N phase-locked loop (PLL) including a dual-mode digital-to-time converter according to one embodiment of the present disclosure;

FIG. 2 is a schematic diagram illustrating an example of the dual-mode digital-to-time converter according to one embodiment of the present disclosure;

FIGS. 3A and 3B are a diagram for explaining a ring oscillator mode of the dual-mode digital-to-time converter according to one embodiment of the present disclosure;

FIG. 4 is a diagram for explaining a digital-to-time converter (DTC) mode of the dual-mode digital-to-time converter according to one embodiment of the present disclosure;

FIG. 5 is a diagram for explaining a dual-mode digital-to-time converter according to another embodiment of the present disclosure;

FIG. 6 is a diagram for explaining a dual-mode digital-to-time converter according to still another embodiment of the present disclosure;

FIG. 7 is a diagram for explaining a dual-mode digital-to-time converter according to still another embodiment of the present disclosure;

FIG. 8 is a schematic diagram illustrating an example of the dual-mode digital-to-time converter including a delay drift detector according to one embodiment;

FIG. 9 is a diagram for explaining the delay drift detector according to one embodiment;

FIG. 10A is a timing diagram for explaining operation of a delay drift detector in a state in which delay drift does not occur; and

FIG. 10B is a timing diagram for explaining operation of a delay drift detector in a state in which delay drift has occurred.

### DETAILED DESCRIPTION OF THE PREFERRED EMBODIMENT

Advantages and features of the present disclosure and methods of accomplishing the same may be understood more readily with reference to the following detailed description of embodiments and the accompanying drawings. However, the present disclosure is not limited to the embodiments set forth herein, and may be embodied in many different forms. The embodiments are provided so that this disclosure will be thorough and complete, and will fully convey the concept of the present disclosure to those skilled in the art. Like reference numerals denote like elements throughout the specification.

As used herein, the term is intended to describe the embodiments but is not intended to limit the present disclosure. In this specification, the singular includes the plural unless specifically stated otherwise. It will be further understood that the terms “comprises,” “comprising,” “includes,” and/or “including,” when used herein, mean that the mentioned components, steps, operations, and/or elements do not exclude the presence or addition of one or more other components, steps, operations and/or elements.

It will be understood that, although the terms first, second, etc. may be used herein to describe various devices or components, the elements or components should not be limited by these terms. These terms are used only to distinguish one element or component from another device or component. Accordingly, a first element or component mentioned below may also a second element or component within the technical idea of the present disclosure.

Unless defined otherwise, all the terms (including technical and scientific terms) used in this specification may be used as meanings that may be commonly understood by those skilled in the art. In addition, terms defined in commonly used dictionaries are not interpreted ideally or excessively unless clearly and specially defined.

Hereinafter, a configuration and operation effects of the present disclosure will be described in detail with reference to the accompanying drawings.

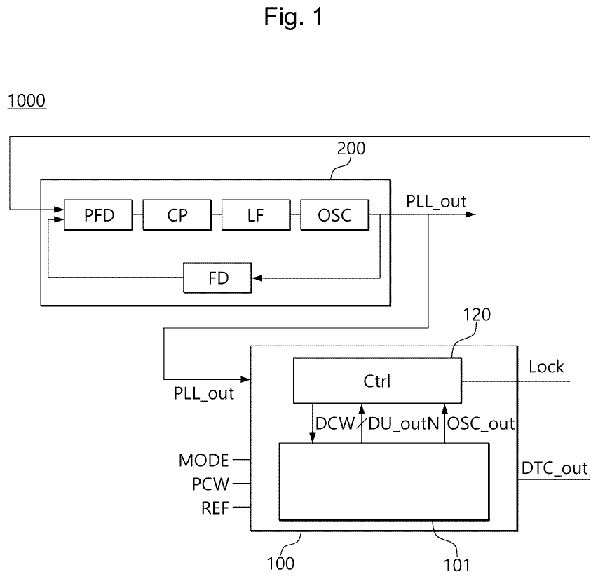

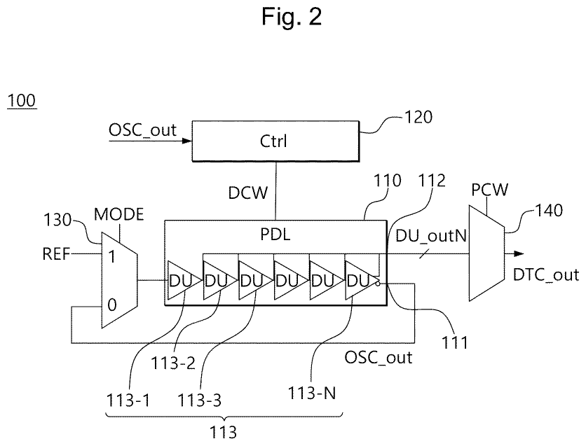

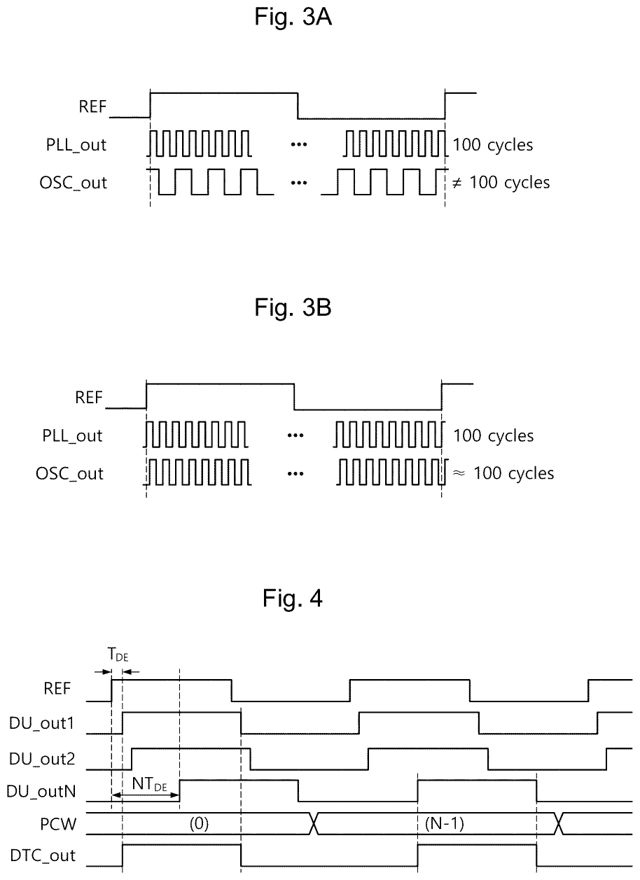

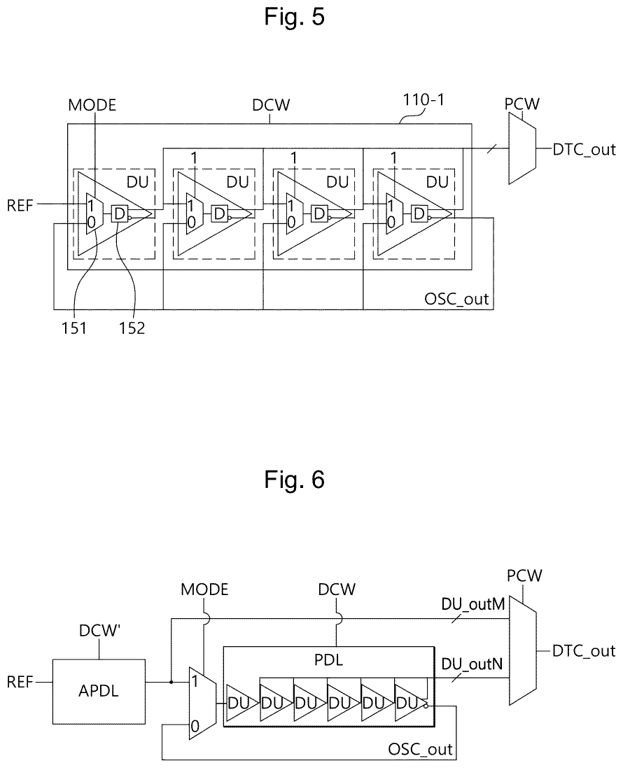

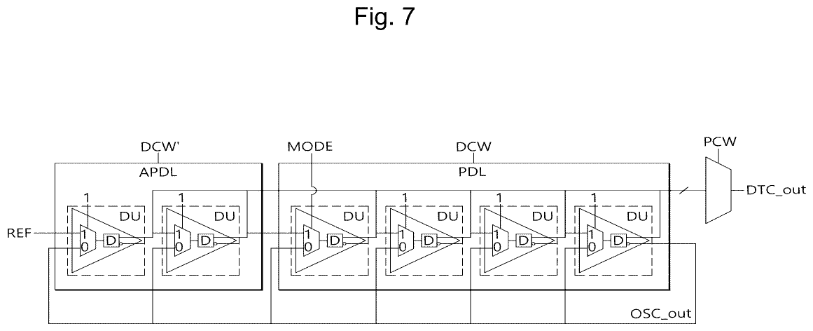

FIG. 1 is a schematic diagram illustrating an example of a fractional-N phase-locked loop (PLL) 1000 including a dual-mode digital-to-time converter 100 according to one embodiment of the present disclosure. FIG. 2 is a schematic diagram illustrating an example of the dual-mode digital-to-time converter 100 according to one embodiment of the present disclosure. FIG. 3 is a diagram for explaining a ring oscillator mode of the dual-mode digital-to-time converter 100 according to one embodiment of the present disclosure. FIG. 4 is a diagram for explaining a digital-to-time converter (DTC) mode of the dual-mode digital-to-time converter 100 according to one embodiment of the present disclosure. FIG. 5 is a diagram for explaining the dual-mode digital-to-time converter 100 according to another embodiment of the present disclosure. FIG. 6 is a diagram for explaining the dual-mode digital-to-time converter 100 according to still another embodiment of the present disclosure. FIG. 7 is a diagram for explaining the dual-mode digital-to-time converter 100 according to still another embodiment of the present disclosure.

FIG. 1 illustrates an example of a phase-locked loop (PLL) 200 implemented as an analog type. The PLL 200 implemented as an analog type may include a phase frequency detector PFD, a charge pump CP, a loop filter LF, an oscillator OSC, a fractional divider FD, etc., and outputs a PLL output clock signal PLL_out. In one embodiment, the oscillator OSC may be implemented as a voltage-controlled oscillator (VCO) or a digitally-controlled oscillator (DCO). Although not shown in the drawings, the PLL may also be digitally implemented. In another embodiment, the PLL may include a phase detector instead of the phase frequency detector.

In one embodiment, the dual-mode digital-to-time converter 100 may receive an input of a reference clock signal REF. The dual-mode digital-to-time converter 100 may output a DTC output clock signal DTC_out that has delayed the reference clock signal REF by first delay time. The DTC output clock signal DTC_out may be provided to the phase-locked loop 200.

In one embodiment, the dual-mode digital-to-time converter 100 may operate in a ring oscillator mode or a DTC mode. In another embodiment, the dual-mode digital-to-time converter 100 may operate in a mode other than the ring oscillator mode and the DTC mode. In the ring oscillator mode, second delay time may be set. That is, a delay control word DCW configured to cause total delay time of the dual-mode digital-to-time converter 100 to be the second delay time may be determined in the ring oscillator mode.

In one embodiment, the dual-mode digital-to-time converter 100 may include a delay block 101 and a controller 120. The delay block 101 may include a programmable delay line (PDL) 110, a first multiplexer 130, and a second multiplexer 140. In another embodiment, the delay block 101 may be implemented as a programmable delay line having a plurality of delay units.

The reference clock signal REF may be applied to a first input terminal of the first multiplexer 130, and a first output stage 111 of the programmable delay line 110 may be connected to a second input terminal of the first multiplexer 130.

In one embodiment, an input terminal of the second multiplexer 140 may be connected to a second output stage 112 of the programmable delay line 110, and an output terminal of the second multiplexer 140 may be connected to an output terminal of the dual-mode digital-to-time converter 100. At this time, the programmable delay line 110 may include a plurality of delay units 113, and an output stage of each of the delay units 113 may be connected to the input terminal of the second multiplexer 140. That is, the second output stage 112 may be implemented as a set of output stages of the respective delay units 113.

In one embodiment, a mode control signal MODE may be applied to the first multiplexer 130. The first multiplexer 130 may output the reference clock signal REF in correspondence with the mode control signal MODE (the DTC mode) or output a signal (a ring oscillator output signal OSC_out) of the first output stage 111 of the programmable delay line 110 (the ring oscillator mode). Here, whenever an operating frequency setting of the phase-locked loop 200 is changed, the DTC output clock signal DTC_out may also need to be changed, and the delay control word DCW may need to be changed to change the DTC output clock signal DTC_out. As described above, when the delay control word DCW needs to be changed, it may be desirable to perform the ring oscillator mode, and then, the DTC mode.

In one embodiment, even when the operating frequency setting of the phase-locked loop 200 is not changed, operation characteristics of the dual-mode digital-to-time converter 100 may be changed to deviate from a predetermined margin of error due to factors such as a temperature change. Even in this case, when an output of the phase-locked loop 200 may be interrupted, the ring oscillator mode may be allowed to performed.

In another embodiment, two dual-mode digital-to-time converters 100 may be provided. In this case, while a first dual-mode digital-to-time converter 100 operates in the DTC mode, a second dual-mode digital-to-time converter 100 may operate in the ring oscillator mode to perform a process of deriving a delay control word DCW suitable for temperature conditions at the time, etc., in advance. Additionally, when the operation characteristics of the first dual-mode digital-to-time converter 100 deviate from a predetermined margin of error, a problem of changing characteristics of the second dual-mode digital-to-time converter 100 may be resolved by connecting the second dual-mode digital-to-time converter 100 to a PLL and allowing the DTC mode to be performed. At this time, when the operation characteristics of the first dual-mode digital-to-time converter 100 deviate the predetermined margin of error, the ring oscillator mode operation of the second dual-mode digital-to-time converter 100 may be allowed to be started, and when the delay control word DCW of the second dual-mode digital-to-time converter 100 is determined, the DTC output clock signal DTC_out of the second dual-mode digital-to-time converter 100 may be provided to the phase-locked loop 200.

In another embodiment, a calibration process may be performed by monitoring changes in operation characteristics of the dual-mode digital-to-time converter 100 and using a result of the monitoring to change the delay control word DCW.

In one embodiment, the programmable delay line 110 includes the delay units 113. An output stage of each of the delay units 113 may be connected to the input terminal of the second multiplexer 140, and the first delay time may be adjusted by operation of the second multiplexer 140.

When the delay control word DCW configured to cause total delay time of the dual-mode digital-to-time converter 100 to be the second delay time is determined, the first delay time may be determined by a phase control word PCW applied to the second multiplexer 140.

In one embodiment, characteristics of the delay units 113 are identical to each other within a margin of error, and when N delay units 113 are provided, the first delay time may be adjusted in units of 1/N of the second delay time.

Referring to FIG. 2, an input terminal of a first delay unit 113-1 may be connected to an input stage of the programmable delay line 110, and an output terminal of the first delay unit 113-1 may be connected to an input terminal of a second delay unit 113-2 and the input terminal of the second multiplexer 140. An output terminal of the second delay unit 113-2 may be connected to an input terminal of the third delay unit 113-3 and the input terminal of the second multiplexer 140. In this way, the delay units 113 may be connected sequentially to each other.

In one embodiment, an Nth delay unit 113-N may include a first output terminal and a second output terminal. The first output terminal of the Nth delay unit 113-N may be connected to the first output stage 111 of the programmable delay line 110, and the second output terminal of the Nth delay unit 113-N may be connected to the second output stage 112 of the programmable delay line 110.

In one embodiment, at least one delay unit including the Nth delay unit 113-N, among the delay units 113, may have a differential structure. Additionally, the first output terminal of the Nth delay unit 113-N may output an inverted signal of the second output terminal. The first output terminal configured to output the inverted signal of the second output terminal is connected to the second input terminal of the first multiplexer 130 via the first output stage 111 of the programmable delay line 110. Accordingly, the first multiplexer 130 and the delay units 113 may constitute a ring oscillator structure.

In another embodiment, although not shown in the drawings, the Nth delay unit may have a single-ended structure to have only one output terminal. In this case, an output terminal of the Nth delay unit may be connected to the input terminal of the second multiplexer 140, and a signal output from the output terminal of the Nth delay unit may be inverted and applied to the first multiplexer 130. Thus, an inverter may be placed between the output terminal of the Nth delay unit and an input terminal of the first multiplexer 130.

In one embodiment, the dual-mode digital-to-time converter 100 may include the controller 120.

In the ring oscillator mode, when a period of the ring oscillator output signal OSC_out is shorter than a predetermined reference, the controller 120 may change the delay control word DCW to increase delay time of the delay units 113, and when a period of the ring oscillator output signal OSC_out is longer than the predetermined reference, the controller 120 may change the delay control word DCW to reduce delay time of the delay units 113. At this time, to determine whether the period of the ring oscillator output signal OSC_out is shorter or longer than a predetermined reference, the ring oscillator output signal OSC_out may be compared with the reference clock signal REF or a PLL output signal. In one embodiment, the delay control word DCW determined in the ring oscillator mode may be stored as a digital code value, and a predetermined value of the delay control word DCW is maintained in a fixed state while the DTC mode is performed. However, as described above, even in the DTC mode, when calibration of the dual-mode digital-to-time converter 100 is needed, the delay control word DCW may be changed.

In one embodiment, the controller 120 may include an auxiliary PLL. At this time, the auxiliary PLL may include a digital filter. In another embodiment, the auxiliary PLL may be implemented to have an analog PLL structure as illustrated in FIG. 1.

FIG. 3A schematically illustrates a state in which, when a frequency of the PLL output clock signal PLL_out is 100 times a frequency of the reference clock signal REF, the ring oscillator output signal OSC_out is not 100 times the frequency of the reference clock signal REF before the ring oscillator mode is completed. In addition, FIG. 3B schematically illustrates a state in which the ring oscillator mode is completed by adjusting the ring oscillator output signal OSC_out to be close to 100 times the frequency of the reference clock signal REF. Referring to FIGS. 3A and 3B, when the dual-mode digital-to-time converter 100 operates in the ring oscillator mode, a number of output periods of a ring oscillator within one period of the reference clock signal REF may be checked. At this time, accuracy may be improved by counting the output periods of the ring oscillator over several periods of the reference clock signal REF. Meanwhile, since an output of the PLL is generated based on the reference clock signal REF, a number of output periods of the PLL during one period or several periods of the reference clock signal REF may be identified in advance. Accordingly, a difference between an output period of the ring oscillator and an output period of the PLL may be calculated. In addition, when this difference is within a predetermined margin of error, the ring oscillator mode may be completed. When a difference between a period of the PLL output clock signal PLL_out and the period of the ring oscillator output signal OSC_out deviates from the predetermined margin of error, the delay control word DCW of the programmable delay line 110 may be adjusted based on a result of the calculation, and then, the above-described process may be repeated. Here, various algorithms may be applied to a process of changing the delay control word DCW. In one embodiment, the delay control word DCW may be set so that total delay time of the dual-mode digital-to-time converter 100 is equal to a period of the phase-locked loop 200 within a predetermined margin of error.

Referring to FIGS. 3A, 3B and 4, when the ring oscillator mode is completed, an output period of the dual-mode digital-to-time converter 100 (the period of the ring oscillator output signal OSC_out) operating in the ring oscillator mode may be adjusted to be almost identical to the period of the PLL output clock signal PLL_out, which is an output signal of the phase-locked loop 200. Meanwhile, when the programmable delay line 110 includes a plurality of delay units (characteristics of the plurality of delay units are similar to each other to a significant degree within an acceptable margin of error), Equation 1 presented below may be satisfied.

T_{PLL}/2N=T_{DE} [Equation 1]
T_{PLL}: a period of the PLL output clock signal PLL_out
T_{DE}=delay time of an individual delay unit
N: a number of delay units

In one embodiment, the dual-mode digital-to-time converter 100 may operate in the DTC mode after the ring oscillator mode is completed. In the DTC mode, the reference clock signal REF may be input to the programmable delay line 110.

In one embodiment, output of each of the delay units 113 included in the programmable delay line 110 may be connected to the input terminal of the second multiplexer 140. At this time, delay unit output signals DU_out1, DU_out2, to DU_outN output from the delay units 113 have different phases, respectively, and a set of the delay unit output signals DU_out1, DU_out2, to DU_outN output from the delay units 113, respectively, may be referred to as multi-phase signals.

In one embodiment, the phase control word PCW may be applied to a control terminal of the second multiplexer 140. The second multiplexer 140 may receive inputs of the multi-phase signals described above, and select and output one of the multi-phase signals. At this time, a signal to be output by the second multiplexer 140, among the multi-phase signals, may be determined by the phase control word PCW.

Meanwhile, when each delay unit 113 has same characteristics, T_{DE} for each delay unit is constant. Thus, delay time of a signal output from the second multiplexer 140 may be changed in units of T_{DE}. Accordingly, the dual-mode digital-to-time converter 100 may operate as a DTC having a resolution of T_{DE}. Additionally, a dynamic range of the dual-mode digital-to-time converter 100 becomes T_{PLL}/2.

In FIG. 4, an output signal connected to the output terminal of the first delay unit is illustrated as DU_out1. At this time, the first delay time is T_{DE}. Additionally, an output signal connected to the output terminal of the second delay unit is illustrated as DU_out2. At this time, first delay time is 2*T_{DE}. An output signal connected to an output terminal of the Nth delay unit is illustrated as DU_outN. At this time, first delay time is N*T_{DE}. In an example illustrated in FIG. 4, it may be checked that the DTC output clock signal DTC_out is identical to DU_out1 in a section in which the phase control word PCW is (0), and the DTC output clock signal DTC_out becomes identical to DU_outN in a section in which the phase control word PCW is (N−1).

Referring to FIG. 5, in one embodiment, an input multiplexer 151 and a delay element 152 may be included within each delay unit DU. Here, each delay unit may have a single-ended structure or a differential structure.

In one embodiment, one input terminal of the input multiplexer 151 may be connected to a first output stage of a programmable delay line 110-1. In addition, the reference clock signal REF may be applied to another input terminal of the input multiplexer 151 or an output stage of a previous delay unit may be connected to the another input terminal of the input multiplexer 151.

In one embodiment, the input multiplexer 151 and the delay element 152 may be included within each of the first to Nth delay units. One input terminal of the input multiplexer 151 included in the first delay unit may be connected to a first output stage of the programmable delay line 110-1, and the reference clock signal REF may be applied to another input terminal of the input multiplexer 151.

In one embodiment, a signal may not be applied to one input terminal of each of the input multiplexers provided in the second to Nth delay units, or the one input terminal of each of the input multiplexers included in the second to Nth delay units may be connected to the first output stage of the programmable delay line 110-1. Additionally, an output stage of a previous delay unit may be connected to another input terminal of each of the input multiplexers included in the second delay unit to the Nth delay unit.

A mode control signal MODE may be applied to a control terminal of the input multiplexer 151 included in the first delay unit, and a first control signal 1 may be applied to each of control terminals of input multiplexers included in delay units other than the first delay unit. The first control signal 1 may be a control signal for causing a signal, output from an output stage of a previous delay unit, to be output.

According to the present embodiment, since an input multiplexer is provided inside each delay unit, linearity between a number of delay unit connections and delay time may be improved compared to a case in which the first multiplexer is provided outside an input stage of the programmable delay line 110-1.

In addition, since each delay unit includes an input multiplexer and a delay element, it may be advantageous to implement the delay units having characteristics identical to each other within a margin of error. In addition, when the first output stage of the programmable delay line is to be connected to an input terminal of each input multiplexer, a difference in characteristics between respective delay units may be further reduced.

In one embodiment, two adjacent signals may be selected from among N multi-phase signals, and phases of the selected two adjacent signals may be interpolated to be output as an output signal DTC_out of the dual-mode digital-to-time converter 100. At this time, this operation may be controlled by the phase control word PCW.

In one embodiment, delay time between an input and an output of the programmable delay line may be adjusted by the delay control word DCW. It is desirable to determine the delay control word DCW in the ring oscillator mode. However, when calibration is needed due to temperature changes, etc., the delay control word DCW may be changed.

Referring to FIG. 6, an auxiliary programmable delay line APDL connected between the first input terminal of the first multiplexer and an input side of the reference clock signal may be further included. At this time, the auxiliary programmable delay line APDL may receive an input of a reference clock signal instead of the first multiplexer, delay the reference clock signal in correspondence with the auxiliary delay control word DCW′, and provide the delayed reference clock signal to the first multiplexer and the second multiplexer. Accordingly, a degree of delay in each of the programmable delay line PDL and the auxiliary programmable delay line APDL may be adjusted by adjusting a multiplexer control signal. In addition, according to the present embodiment, a dynamic range of the dual-mode digital-to-time converter may be increased. When a number of delay units included in the auxiliary programmable delay line APDL is M, the dynamic range may be increased by T_{PLL}/(2N)*(N+M). In one embodiment, when a same programmable delay line sharing a delay control word DCW is utilized, then, M=N, and thus, the dynamic range may be doubled compared to a previous dynamic range.

Referring to FIG. 7, even in an embodiment in which an input multiplexer and a delay element are included in each delay unit, an effect similar to that of the embodiment described with reference to FIG. 6 may be implemented by providing an auxiliary delay line.

In one embodiment, a dynamic range may also be adjusted by changing a period of the ring oscillator output signal OSC_out compared in the ring oscillator mode.

When a frequency of the ring oscillator output signal OSC_out in the ring oscillator mode is K times a frequency of the PLL output clock signal PLL_out of the phase-locked loop 200, Equation 2 expressed below may be satisfied.

1/(2N·T_{DE})=K/T_{PLL} [Equation 2]
T_{PLL}: a period of the PLL output clock signal PLL_out
T_{DE}=delay time of an individual delay unit
N: a number of delay units

In this case, the dual-mode digital-to-time converter 100 may operate as a DTC with a resolution of T_{DE}=T_{PLL}/(2N·K) and a dynamic range of T_{PLL}/(2K).

That is, when K=½, a resolution is T_{PLL}/N, and a dynamic range is T_{PLL.}

When K=2, a resolution is T_{PLL}/(4N), and a dynamic range is T_{PLL}/4.

As described above, a trade-off between a resolution and a dynamic range may be obtained by adjusting K.

### Calibration

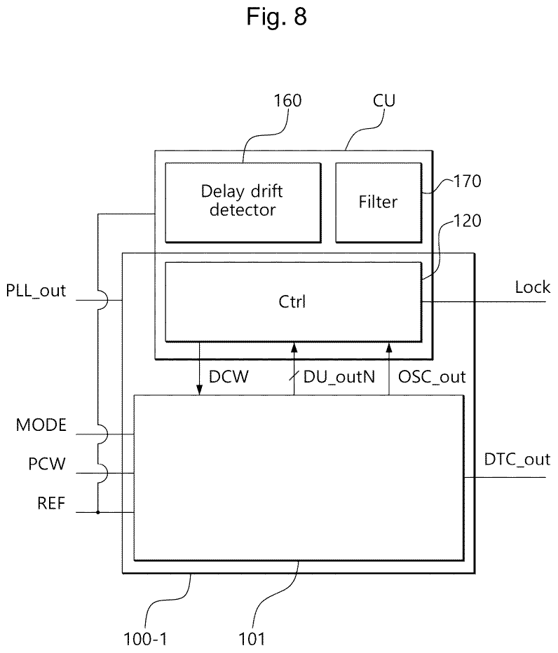

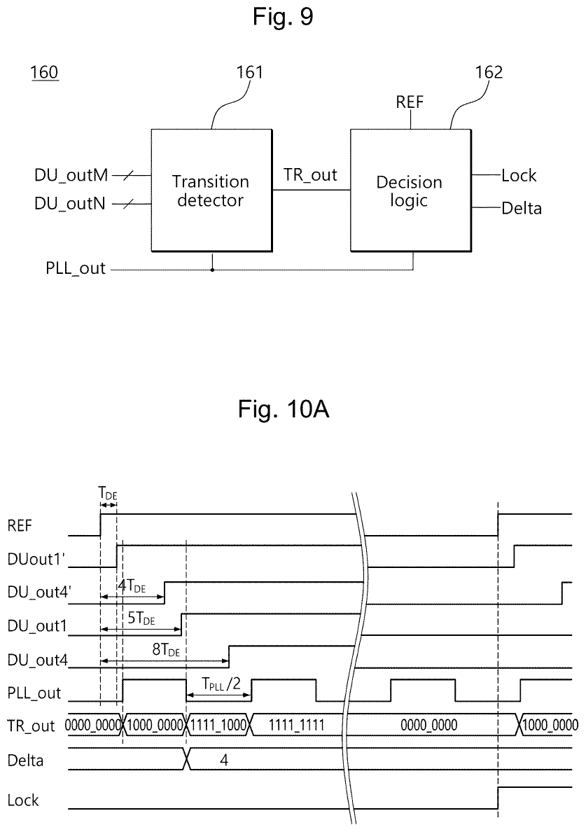

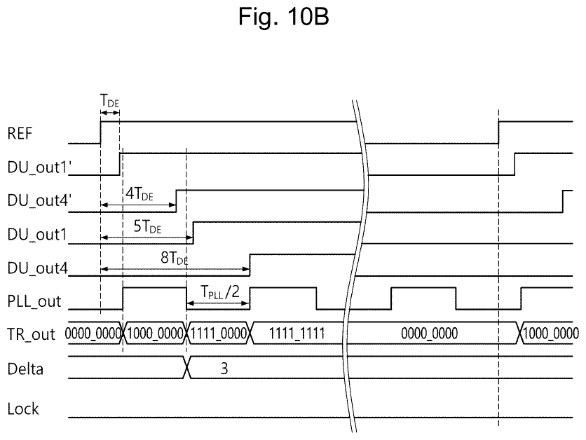

FIG. 8 is a schematic diagram illustrating an example of a dual-mode digital-to-time converter 100-1 including a delay drift detector 160 according to one embodiment. FIG. 9 is a diagram for explaining the delay drift detector 160 according to one embodiment. FIG. 10A is a timing diagram for explaining operation of the delay drift detector 160 in a state in which delay drift does not occur. FIG. 10B is a timing diagram for explaining operation of the delay drift detector 160 in a state in which delay drift has occurred.

According to a change in a power voltage or a temperature during operation of a phase-locked loop, a phenomenon (hereinafter referred to as “delay drift”) in which delay time of delay units included in the dual-mode digital-to-time converter 100-1 deviates from an initial set value (which may also include a value set through the ring oscillator mode) may occur.

According to one embodiment of the present disclosure, whether delay time that was initially set is changed beyond a predetermined margin of error may be monitored. In addition, according to a result of the monitoring, when the delay time is changed beyond the predetermined margin of error, a set value for the initially set delay time (e.g., a delay control word) may be calibrated. Accordingly, even when a change in a power voltage or a temperature occurs, accuracy of the dual-mode digital-to-time converter 100-1 may be maintained. The delay drift detector 160 may be included to monitor the delay drift.

In one embodiment, the delay drift detector 160 may include a transition detector 161 and a decision logic 162. Meanwhile, the delay drift detector 160 may be included in a controller or provided separately from the controller. Additionally, a control unit CU including the controller and the delay drift detector 160 may be provided. Additionally, in one embodiment, the control unit CU may further include a filter 170. At this time, the control unit CU may be connected to the delay block 101. As described above with reference to FIGS. 1 and 2, etc., the delay block 101 may include the programmable delay line 110, the first multiplexer 130, and the second multiplexer 140. In another embodiment, the delay block 101 may be implemented as a programmable delay line having a plurality of delay units.

The transition detector 161 may sample multi-phase signals DU_out1, DU_out2, . . . DU_outN, DU_out1′, DU_out2′, . . . to DU_outM output from the delay unit. At this time, the transition detector 161 may perform a sampling process using the PLL output clock signal PLL_out. In addition, the transition detector 161 may check a number of transitions (which may be referred to as ‘delay unit transitions’) occurring in output of each delay unit during predetermined time. In addition, by checking whether a result actually measured by the transition detector 161 matches an expected value in a normal state, whether total delay time characteristics determined by the delay control word DCW is within the margin of error may be determined.

In one embodiment, since total measurement time by the delay drift detector 160 needs to be less than or equal to a dynamic range, a measurement time interval for which a number of transitions is measured may be configured to be inversely proportional to a number of times for measurements.

In one embodiment, the delay drift detector 160 may check whether an increase in the number of the transitions according to the measurement time interval matches the expected value.

For example, a dynamic range of the dual-mode digital-to-time converter 100 including the auxiliary programmable delay line 110 with M=N is T_{PLL} and transitions of a total of 2N delay units may be present at regular intervals. Therefore, when measurements are performed twice at intervals of T_{PLL}/2 based on a case when delay time is in a normal state, a number of transitions of the delay units which increase between the two measurements is N.

In FIG. 10A, a number of delayed signals in which a transition occurs during a unit interval (UI=T_{PLL}/2) is output as TR_out. Here, the unit interval may be determined as being less than or equal to half of a period T_{PLL} of the PLL output clock signal PLL_out. For example, the unit interval may be determined as T_{PLL}/2, T_{PLL}/3, T_{PLL}/4, T_{PLL}/5, T_{PLL}/6, T_{PLL}/7, T_{PLL}/8, or the like. At this time, when the dynamic range is T_{PLL} and transitions of a total of 2N delay unit are present at regular intervals, and when measurements are performed twice at intervals of T_{PLL}/4 based on a case when delay time is in a normal state, a number of transitions of the delay units which increase between the two measurements is N/2. According to the same principle, when measurements are performed twice at intervals of T_{PLL}/8 based on a case when delay time is in a normal state, a number of transitions of the delay units which increase between the two measurements is N/4.

As described above, a difference between a number of transitions in a previous unit interval and a number of transitions in a present unit interval may be obtained. By comparing a value of the difference (an increase amount) with a predetermined reference value, whether total delay time of the programmable delay line has decreased or increased compared to a normal state may be determined. When the unit interval exceeds half of the T_{PLL}, whether the delay time has increased or decreased compared to the normal state may not be accurately determined by a detected number of transitions.

In FIG. 10A, delta means a difference between TR_out of the previous unit interval and TR_out of a corresponding unit interval, and may mean an amount of increase in the transitions. Depending on a method of implementing the delay drift detector 160, when transitions in a particular unit interval are counted, transitions that occurred before the corresponding unit interval may be also counted. In this case, it may be desirable to detect a number of transitions by obtaining an increase amount (Delta) by subtracting a counted number of transitions that occurred in the previous unit interval from a number of transitions counted in the corresponding unit interval.

For example, referring to FIGS. 10A and 10B, in a situation in which M=N=4 and delay drift is not present when measurement is performed twice, a timing diagram as shown in FIG. 10A is derived, and an amount of increase in transitions is 4.

However, when delay time of a delay unit becomes longer than a preset value (a value in a normal state) due to occurrence of a delay drift for a certain reason, a timing diagram as illustrated in FIG. 10B is derived, and an amount of increase in transitions is reduced to 3.

Conversely, although not shown in the drawing, when delay time of a delay unit is shorter than a preset value (a value in a normal state), an amount of increase in transitions becomes 5.

By detecting a number of transitions of a delay unit as described above, whether delay drift has occurred may be detected. Meanwhile, as illustrated in FIG. 10B, when a number of transitions of a delay unit is decreased compared to a reference, it may be determined that delay drift in which delay time is increased compared to a reference has occurred. In this case, calibration may be performed to reduce a set value for the delay time of the delay unit.

On the other hand, when a number of transitions of a delay unit is increased compared to a reference, it may be determined that delay drift in which the delay time is decreased compared to a reference. In this case, calibration may be performed to increase a set value for the delay time of the delay unit.

In one embodiment, a detection result by the delay drift detector 160 may be provided to the dual-mode digital-to-time converter 100, and the dual-mode digital-to-time converter 100 may calibrate delay drift by taking measures such as adjusting a delay control word DCW.

In one embodiment, when a delay control word needed to lower an amount of increase in transitions by one step or a delay control word needed to raise an amount of increase in transitions by one step is identified in advance, the corresponding delay control word may be reflected in a previous delay control word to calibrate the delay control word.

Accordingly, calibration may be performed on an on-time (real-time) basis without interruption of DTC or PLL operation.

In one embodiment, a Lock signal illustrated in FIG. 10A or the like may be used as a signal for the controller to notify another adjacent circuit of a normal state when a signal is output with stable delay time without delay drift. For example, a state in which the Lock signal is 1 may mean a state in which the dual-mode digital-to-time converter 100 may output a DTC output clock signal DTC_out while performing normal operation, and a state in which the Lock signal is 0 may mean a state in which the dual-mode digital-to-time converter 100 cannot output a delayed signal within a predetermined margin of error.

In one embodiment, an error between an actual measured amount of increase (Delta) in transitions and an expected value of increase in the transitions may be accumulated and filtered. In addition, delay drift may be calibrated by modifying the delay control word DCW of the dual-mode digital-to-time converter 100 using a value obtained as a result of the filtering.

In one embodiment, a calibration function may be applied to not only a dual-mode digital-to-time converter, but also a general digital-to-time converter including a plurality of delay units (e.g., a digital-to-time converter in which the delay unit 101 is implemented as the programmable delay line PDL and operates only in the DTC mode). As such, a digital-to-time converter capable of performing calibration may be referred to as a digital-to-time converter having a calibration function.

In one embodiment, in the dual-mode digital-to-time converter described above, in a state when a delay control word DCW appropriate for generating a DTC output clock signal DTC_out suitable to generate a required PLL output clock signal PLL_out is determined, the PLL output clock signal PLL_out may be used outside the phase-locked loop. At this time, the appropriate delay control word DCW may be determined while the dual-mode digital-to-time converter operates in the ring oscillator mode. When the appropriate delay control word DCW is determined, while the phase-locked loop is operating normally, the delay control word DCW may be finely adjusted through a calibration function. Thus, calibration may be performed on an on-time basis (in real time) without interrupting the DTC or PLL operation.

In another embodiment, even when a calibration function is applied to a digital-to-time converter including a plurality of delay units, the calibration function according to one embodiment of the present disclosure may be applied in a state when a delay control word DCW appropriate for causing the digital-to-time converter to output a required DTC output clock signal DTC_out is determined. Accordingly, by finely adjusting the delay control word DCW through the calibration function, calibration may be performed on an on-time basis (in real time) without interrupting the DTC or PLL operation.

In another embodiment, two identical dual-mode digital-to-time converters 100 are may be provided, and while one dual-mode digital-to-time converter 100 is operating in the DTC mode, another dual-mode digital-to-time converter 100 may be configured to operate in the ring oscillator mode to thereby set a delay control word DCW. At this time, when delay drift is detected in the dual-mode digital-to-time converter 100 operating in the DTC mode, the dual-mode digital-to-time converter 100 operating in the ring oscillator mode may be changed into the DTC mode to provide a DTC output clock signal DTC_out to the phase-locked loop. Thus, a delay drift problem may be resolved.

According to one embodiment of the present disclosure, a useful effect of reducing power consumption and having a reduced area while having a resolution and a dynamic range sufficient to remove quantization noise used in a fractional divider may be obtained

In addition, according to one embodiment of the present disclosure, calibration may be performed on an on-time (real-time) basis without interruption of digital-to-time converter (DTC) or phase-locked loop (PLL) operation.

Although the present disclosure has been described with reference to one embodiment illustrated in the drawings, this is only an example, and it will be understood by those of ordinary skill in the art that various changes in the form and details may be made therein without departing from the idea and scope of the present disclosure as defined by the appended claims.

What is claimed is:

1. A dual-mode digital-to-time converter for a phase-locked loop, the dual-mode digital-to-time converter being configured to be utilized for a phase-locked loop comprising a fractional divider,
wherein the dual-mode digital-to-time converter provides, to the phase-locked loop, a digital-to-time converter output clock signal that has delayed a reference clock signal by first delay time,
an operating mode of the dual-mode digital-to-time converter comprises a ring oscillator mode and a DTC mode,
in the ring oscillator mode, a delay control word configured to cause total delay time of the dual-mode digital-to-time converter to be second delay time while the dual-mode digital-to-time converter operates as a ring oscillator is determined, and
in the DTC mode, the DTC output clock signal is output when the delay control word determined in the ring oscillator mode is fixed.

2. The dual-mode digital-to-time converter of claim 1, comprising a first multiplexer, a programmable delay line, and a second multiplexer,
wherein the reference clock signal is applied through a first input terminal of the first multiplexer,
an output terminal of the first multiplexer is connected to an input stage of the programmable delay line,
a first output stage of the programmable delay line is connected to a second input terminal of the first multiplexer,
a second output stage of the programmable delay line is connected to an input terminal of the second multiplexer, and
an output terminal of the second multiplexer outputs the DTC output clock signal.

3. The dual-mode digital-to-time converter of claim 2, wherein the programmable delay line comprises delay units, and
an output stage of each of the delay units is connected to the input terminal of the second multiplexer.

4. The dual-mode digital-to-time converter of claim 3, wherein the first delay time is determined by a phase control word applied to the second multiplexer,
with respect to the delay units, N delay units are arranged and characteristics of the delay units are identical to each other within a margin of error, and
the first delay time is adjusted in units of 1/N of the second delay time.

5. The dual-mode digital-to-time converter of claim 2, wherein the programmable delay line comprises a first delay unit, a second delay unit, and a third delay unit,
an input terminal of the first delay unit is connected to the input stage of the programmable delay line,
an output terminal of the first delay unit is connected to an input terminal of the second delay unit and the input terminal of the second multiplexer, and
an output terminal of the second delay unit is connected to an input terminal of the third delay unit and the input terminal of the second multiplexer.

6. The dual-mode digital-to-time converter of claim 5, wherein a number of delay units comprised in the programmable delay line is N,
among the delay units comprised in the programmable delay line, a delay unit in an Nth place is an Nth delay unit,
the Nth delay unit comprises a first output terminal and a second output terminal,
a first output terminal of the Nth delay unit is connected to the first output stage of the programmable delay line,
a second output terminal of the Nth delay unit is connected to the second output stage of the programmable delay line,
the first delay time is determined by a phase control word applied to the second multiplexer,
characteristics of the delay units are identical to each other within a margin of error, and
the first delay time is adjusted in units of 1/N of the second delay time.

7. The dual-mode digital-to-time converter of claim 1, comprising a programmable delay line comprising a first delay unit to an Nth delay unit, and a second multiplexer,
wherein an input multiplexer and a delay element are comprised in each of the first delay unit to the Nth delay unit,
one input terminal of the input multiplexer comprised in the first delay unit is connected to a first output stage of the programmable delay line,
a reference clock signal is applied to another input terminal of the input multiplexer comprised in the first delay unit, and an output terminal of a previous delay unit is connected to another input terminal of each of the input multiplexers comprised in the second to Nth delay units,
a mode control signal is applied to a control terminal of the input multiplexer provided in the first delay unit,
a first control signal is applied to a control terminal of each of the input multiplexers comprised in the second delay unit to the Nth delay unit, and
the first control signal is a control signal configured to output a signal, the signal being output from the output stage of the previous delay unit.

8. The dual-mode digital-to-time converter of claim 1, comprising a first dual-mode digital-to-time converter and a second dual-mode digital-to-time converter,
wherein, while the first dual-mode digital-to-time converter operates in the DTC mode, the second dual-mode digital-to-time converter operates in the ring oscillator mode to set the delay control word, and
the second dual-mode digital-to-time converter, having operated in the ring oscillator mode, is changed into the DTC mode and outputs the DTC output clock signal instead of the first dual-mode digital-to-time converter.

9. The dual-mode digital-to-time converter of claim 2, further comprising an auxiliary programmable delay line connected between the first input terminal of the first multiplexer and an input side of the reference clock signal,
wherein the auxiliary programmable delay line is configured to:
receive an input of a reference clock signal instead of the first multiplexer, and
delay the reference clock signal in correspondence with an auxiliary delay control word and provide the delayed reference clock signal to the first multiplexer and the second multiplexer.

10. The dual-mode digital-to-time converter of claim 3, further comprising:
a transition detector configured to sample delay unit output signals output from the delay units, respectively, and detect a number of transitions which occur in the delay unit output signals during predetermined time; and
a decision logic configured to check whether the number of the transitions detected by the transition detector matches an expected number of transitions in a normal state.

11. The dual-mode digital-to-time converter of claim 10, wherein the transition detector samples the delay unit output signals using an output clock signal of the phase-locked loop, and
the delay control word is calibrated to increase the second delay time when a value obtained by subtracting an expected value of transitions in the normal state from the number of the transitions detected by the transition detector is greater than a predetermined reference value.

12. The dual-mode digital-to-time converter of claim 10, wherein the predetermined time is determined as being less than or equal to a half period of a PLL clock output signal output from the phase-locked loop.
